(19) United States
(12) Patent Application Publication
(10) Pub. No.: US 2025/0234509 A1
(43) Pub. Date: Jul. 17, 2025

(54) SEMICONDUCTOR DEVICE

(71) Applicant: Samsung Electronics Co., Ltd., Suwon-si (KR)

(72) Inventors: Sukhwan CHUNG, Suwon-si (KR); Jonguk KIM, Suwon-si (KR); Dongho AHN, Suwon-si (KR); Minseo YOON, Suwon-si (KR)

(73) Assignee: Samsung Electronics Co., Ltd., Suwon-si (KR)

(21) Appl. No.: 18/938,486

(22) Filed: Nov. 6, 2024

(30) Foreign Application Priority Data
Jan. 11, 2024 (KR) 10-2024-0004861

(51) Int. Cl. H10B 12/00

(52) U.S. Cl. CPC H10B 12/315; H10B 12/05

(57) ABSTRACT

A semiconductor device including a bit line on a substrate, a mold layer over the bit line and including a mold opening having a first sidewall and a second sidewall opposed to each other, a channel layer conformally extending on the mold opening, a plurality of word lines respectively on the first sidewall and the second sidewall of the mold opening, and a gate insulating layer between the plurality of word lines and the channel layer. The channel layer includes a first channel layer composed of amorphous material, and a second channel layer on the first channel layer, the second channel layer being composed of crystalline material.

### CROSS-REFERENCE TO RELATED APPLICATION

This application claims priority under 35 U.S.C. § 119 to Korean Patent Application No. 10-2024-0004861, filed on Jan. 11, 2024, in the Korean Intellectual Property Office, the disclosure of which is incorporated by reference herein in its entirety.

### BACKGROUND

The inventive concepts relate to semiconductor devices, and more particularly, to semiconductor devices including vertical channel transistor structures.

As electronic products are required to become more compact, multi-functional, and provide high-performance, there is a demand for higher capacity and higher integration of semiconductor devices. Due to the downscaling of semiconductor devices, much research is being conducted to reduce the size of dynamic random-access memory (DRAM) devices. As part of this research, a transistor using an oxide semiconductor material as a channel layer was proposed, in a DRAM device with a 1T-1C structure in which one capacitor is connected to one transistor.

### SUMMARY

Some example embodiments of the inventive concepts provide a semiconductor device having improved electrical characteristics by reducing oxidation of bit lines.

Some example embodiments of the inventive concepts provide a semiconductor device that includes a bit line on a substrate; a mold layer over the bit line, the mold layer defining a mold opening, and the mold opening having a first sidewall and a second sidewall opposed to each other; a channel layer conformally extending on the mold opening; a plurality of word lines respectively on the first sidewall and the second sidewall of the mold opening; and a gate insulating layer between the plurality of word lines and the channel layer. The channel layer includes a first channel layer composed of amorphous material, and a second channel layer on the first channel layer, the second channel layer being composed of a crystalline material.

Some example embodiments of the inventive concepts further provide a semiconductor device that includes a bit line extending in a horizontal direction on a substrate; a mold layer covering a portion of an upper surface of the bit line, the mold layer extending in a vertical direction from the upper surface of the bit line; a channel layer covering a sidewall of the mold layer and covering a remaining portion of the upper surface of the bit line that is not covered by the mold layer; a gate insulating layer conformally extending on the channel layer and covering the channel layer; and a plurality of word lines having sidewalls facing sidewalls of the channel layer, the plurality of word lines being spaced apart from each other between the channel layer and the gate insulating layer. The channel layer includes a first channel layer connected to the bit line, the first channel layer including an oxide semiconductor material containing at least one metal element selected from indium, gallium, and zinc, and the oxide semiconductor material being an amorphous material; and a second channel layer spaced apart from the bit line, the first channel layer being between the second channel layer and the bit line. A thickness of the first channel layer is within 30 to 50 angstroms.

Some example embodiments of the inventive concepts still further provide a semiconductor device that includes a plurality of bit lines each extending in a first horizontal direction on a substrate and spaced apart from each other in a second horizontal direction intersecting the first horizontal direction; a mold layer covering a portion of an upper surface of a bit line from among the plurality of bit lines, the mold layer extending in a vertical direction from the upper surface of the bit line; a channel layer covering sidewalls of the mold layer and covering a remaining portion of the upper surface of the bit line that is not covered by the mold layer; a gate insulating layer conformally extending on the channel layer and covering the channel layer; a plurality of word lines having sidewalls facing sidewalls of the channel layer, the plurality of word lines being spaced apart from the channel layer in the first horizontal direction, and the gate insulating layer being between the plurality of word lines and the channel layer; an insulating barrier wall between the plurality of word lines and separating the plurality of word lines from one another; an insulating liner conformally covering sidewalls and a lower surface of the insulating barrier wall; and a plurality of conductive contact patterns over the channel layer and connected to the channel layer. The channel layer includes a first channel layer connected to the bit line, the first channel layer being amorphous IGZO; and a second channel layer spaced apart from the bit line, the first channel layer being between the second channel layer and the bit line, the second channel layer being crystalline IGZO.

### BRIEF DESCRIPTION OF THE DRAWINGS

Embodiments will be more clearly understood from the following detailed description taken in conjunction with the accompanying drawings in which:

FIG. 1 is a layout view of a semiconductor device according to some example embodiments;

FIG. 2 is a magnified view of a portion of a cell array area of FIG. 1;

FIG. 3A is a cross-sectional view of a semiconductor device according to some example embodiments;

FIG. 3B is an enlarged view of a region “EX” in FIG. 3A;

FIG. 4 is a cross-sectional view for explaining a semiconductor device according to some example embodiments; and

FIGS. 5, 6, 7, 8, 9, 10, 11, 12, 13, 14 and 15 are cross-sectional views for explaining a method of manufacturing a semiconductor device, according to some example embodiments.

### DETAILED DESCRIPTION

To clarify the present disclosure, parts that are not connected with the description will be omitted, and the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

The term “connected” may be used herein to refer to a physical and/or electrical connection and may refer to a direct or indirect physical and/or electrical connection.

It will be understood that when an element or layer is referred to as being “connected to” another element or layer, it may be directly connected to the other element or layer, or one or more intervening elements or layers may be present. In contrast, when an element is referred to as being “directly connected to” another element, there are no intervening elements present.

It will be understood that when an element or layer is referred to as being “over,” “above,” “on,” “below,” “under,” “beneath,” another element or layer, it can be directly over, above, on, below, under, beneath the other element or layer or intervening elements or layers may be present. In contrast, when an element is referred to as being “directly over,” “directly above,” “directly on,” “directly below,” “directly under,” “directly beneath,” another element or layer, there are no intervening elements or layers present.

It will be further understood that the terms “comprises,” “comprising,” “includes” and/or “including,” when used herein, specify the presence of stated features, steps, operations, elements and/or components, but do not preclude the presence or addition of one or more other features, steps, operations, elements, components and/or groups thereof.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes. When ranges are specified, the range includes all values therebetween such as increments of 0.1%.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

Embodiments will now be described more fully with reference to the accompanying drawings. In the accompanying drawings, like reference numerals may refer to like elements, and repeated descriptions of the like elements will be omitted.

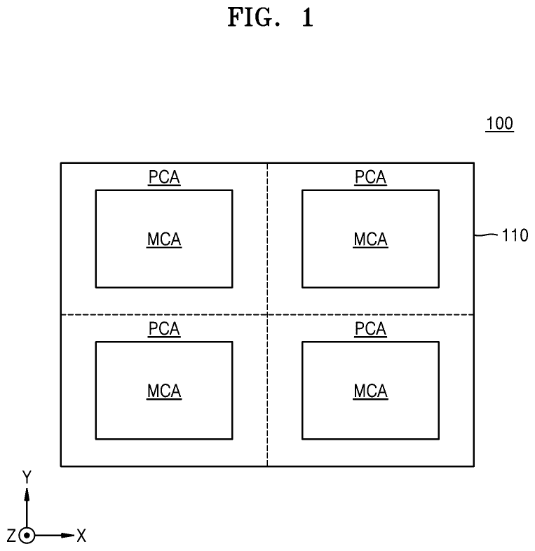

FIG. 1 is a layout view of a semiconductor device 100 according to some example embodiments.

Referring to FIG. 1, the semiconductor device 100 may include a substrate 110 including a cell array area MCA and a peripheral circuit area PCA. According to some example embodiments, the cell array area MCA may be a memory cell area of a DRAM device, and the peripheral circuit area PCA may be a core area or peripheral circuit area of the DRAM device. For example, the peripheral circuit area PCA may include peripheral circuit transistors (not shown) for transmitting signals and/or power to a memory cell array included in the cell array area MCA. According to some example embodiments, the peripheral circuit transistors (not shown) may form various circuits such as a command decoder, a control logic, an address buffer, a row decoder, a column decoder, a sense amplifier, and a data input/output circuit.

In FIG. 1, the cell array area MCA may be arranged in the substrate 110, and the peripheral circuit area PCA is arranged adjacent to the cell array area MCA. However, an arrangement relationship between the cell array area MCA and the peripheral circuit area PCA is not limited thereto, and the peripheral circuit area PCA may be disposed in the substrate 110, and the cell array area MCA may be disposed in the peripheral circuit area PCA.

Herein, a direction in which the substrate 110 extends may be defined as a first horizontal direction (direction X), a direction intersecting the first horizontal direction (direction X) may be defined as a second horizontal direction (direction Y), and a direction perpendicular to an upper surface of the substrate 110 may be defined as a vertical direction (direction Z).

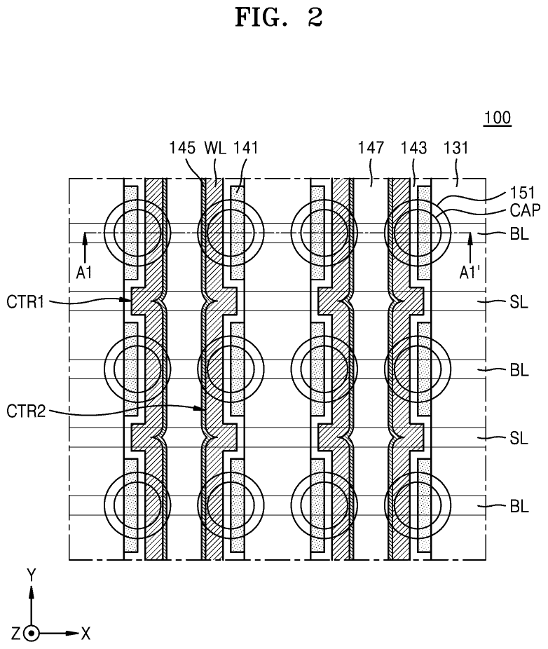

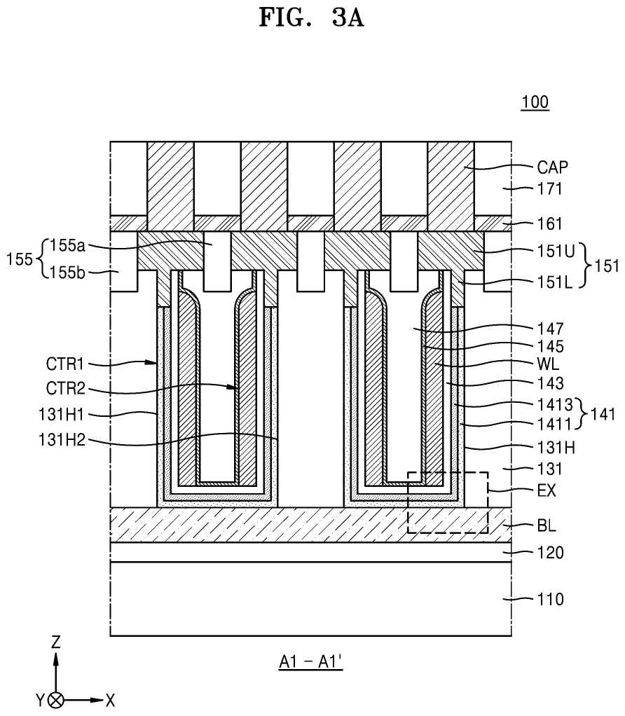

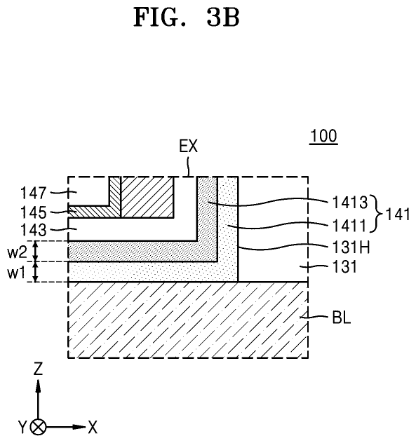

FIG. 2 is a magnified view of a portion of the cell array area MCA of FIG. 1. FIG. 3A is a cross-sectional view of the semiconductor device 100 according to some example embodiments. FIG. 3A is a cross-sectional view taken along line A1-A1′ in FIG. 2. FIG. 3B is an enlarged view of a region “EX” in FIG. 3A.

Referring to FIGS. 2, 3A, and 3B, the semiconductor device 100 may include a substrate 110, a lower insulating layer 120, a plurality of bit lines BL disposed on the lower insulating layer 120, and a plurality of shielding lines SL disposed on the lower insulating layer 120.

According to some example embodiments, the substrate 110 may include a silicon semiconductor, for example, single-crystalline silicon, polycrystalline silicon, or amorphous silicon. The substrate 110 may include a Ge semiconductor, or a compound semiconductor such as SiGe, SiC, GaAs, InAs, InGaAs, or InP. Terms “SiGe”, “SiC”, “GaAs”, “InAs”, “InGaAs”, and “InP” used herein refer to materials composed of elements respectively included in these terms, and are not chemical formulas indicating stoichiometric relationships. The substrate 110 may include a conductive region, for example, an impurity-doped well or an impurity-doped structure.

The lower insulating layer 120 may be disposed on the substrate 110. The lower insulating layer 120 may extend in the first horizontal direction (e.g., an X direction) and the second horizontal direction (e.g., a Y direction), along the direction in which the substrate 110 extends. The lower insulating layer 120 may include an oxide layer, a nitride layer, or a combination thereof.

The plurality of bit lines BL and the plurality of shielding lines SL, each extending in the first horizontal direction (e.g., the X direction), may be disposed on the lower insulating layer 120. The plurality of bit lines BL and the plurality of shielding lines SL may be arranged apart from each other in the second horizontal direction (e.g., the Y direction), and each of the plurality of bit lines BL and each of the plurality of shielding lines SL may be arranged to alternate with each other. For example, one shielding line SL may be placed between two adjacent bit lines BL.

According to some example embodiments, the plurality of bit lines BL may include Ti, TiN, Ta, TaN, W, WN, TiSiN, WSiN, polysilicon, or a combination thereof. For example, the plurality of bit lines BL may include a conductive layer (not shown), and conductive barrier layers (not shown) disposed on an upper surface and a lower surface of the conductive layer, respectively. According to some example embodiments, each of the plurality of shielding lines SL may be made of, but is not limited to, W, Al, Cu, or a combination thereof. According to some example embodiments, each of the plurality of shielding lines SL may include a conductive layer made of W, Al, Cu, or a combination thereof, and an air gap or void inside the conductive layer.

A bit line insulating layer (not shown) may be interposed between one bit line BL selected from the plurality of bit lines BL and a shielding line SL adjacent thereto. The bit line insulating layer may extend in the first horizontal direction (e.g., the X direction) along the extension direction of the bit line BL, and may surround both sidewalls of the bit line BL in the second horizontal direction (e.g., the Y direction). For example, the bit line insulating layer may extend in the first horizontal direction (e.g., the X direction) along the extension direction of the shielding line SL, and may surround both sidewalls of the shielding line SL in the second horizontal direction (e.g., the Y direction). For example, the bit line insulating layer may fill a space between one bit line BL selected from the plurality of bit lines BL and a shielding line SL adjacent thereto, and may be formed on the same level as the plurality of bit lines BL.

A mold layer 131 may be disposed on a plurality of bit lines BL, a plurality of shielding lines SL, and the bit line insulating layer. The mold layer 131 may extend in the vertical direction (e.g., a Z direction) on the plurality of bit lines BL and the bit line insulating layer. The mold layer 131 may include at least one of silicon oxide, silicon nitride, and silicon oxynitride. The mold layer 131 may include a plurality of mold openings 131H. For example, the mold layer 131 may define a plurality of mold openings 131H therein. The plurality of mold openings 131H may have a first sidewall 131H1 and a second sidewall 131H2 that are opposite to each other. An upper surface of the bit line BL may be exposed via the bottom of each of the plurality of mold openings 131H.

A plurality of channel layers 141 may be disposed on a plurality of bit lines BL, a plurality of shielding lines SL, and the bit line insulating layer. Each of the plurality of channel layers 141 may extend conformally along inner walls of the plurality of mold openings 131H. Accordingly, respective outer walls of the plurality of channel layers 141 may contact the mold layer 131. The channel layer 141 may include a portion extending along the bottom of the mold opening 131H, and a portion extending in the vertical direction (e.g., the Z direction) along the first sidewall 131H1 and the second sidewall 131H2 of the mold opening 131H. The bottom of the channel layer 141 may contact the upper surface of the bit line BL exposed via the bottom of the mold opening 131H, and the upper surface of the channel layer 141 may contact a conductive contact pattern 151. For example, the upper surface of the channel layer 141 may be at a lower level in the vertical direction (e.g., the Z direction) than an upper surface of the mold layer 131.

According to some example embodiments, the plurality of channel layers 141 may each include a first channel layer 1411 and a second channel layer 1413 on the first channel layer 1411. For example, the first channel layer 1411 may extend conformally along the inner walls of the plurality of mold openings 131H, and the second channel layer 1413 may extend conformally on the first channel layer 1411.

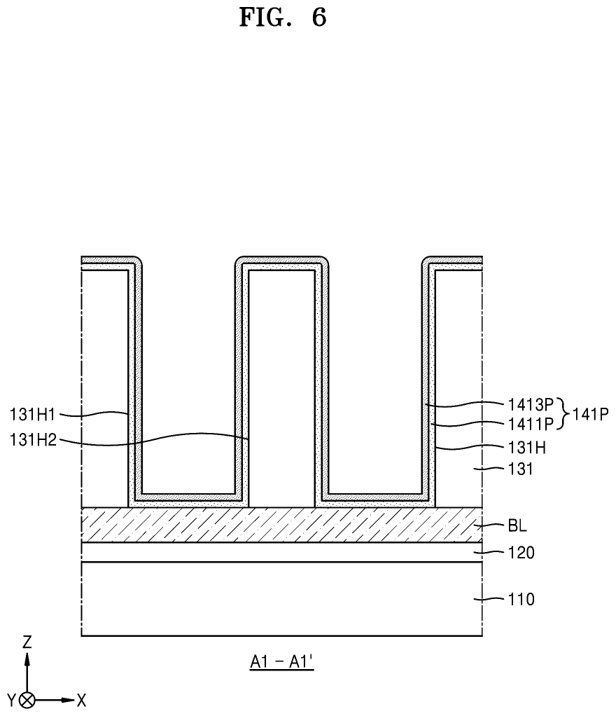

According to some example embodiments, the first channel layer 1411 may be formed of an amorphous material, and the second channel layer 1413 may be formed of a crystalline material. According to some example embodiments, the crystallinity of the second channel layer 1413 may be 17% or more and 100% or less. In a process, an oxygen partial pressure may be adjusted to 0% or more and less than 10% during a deposition process of the first channel layer 1411, so that the first channel layer 1411 may be formed of an amorphous material. An oxygen partial pressure may be adjusted to 10% or more and less than 100% during a deposition process of the second channel layer 1413, so that the second channel layer 1413 may be formed of a crystalline material. Because the deposition process of the first channel layer 1411 is performed under such oxygen partial pressure conditions, oxidation of the bit line BL disposed below the first channel layer 1411 may be reduced. Because the deposition process of the second channel layer 1413 is performed under such oxygen partial pressure conditions, the second channel layer 1413 may be formed as a crystalline material, thereby limiting and/or preventing the mobility of carriers within the channel layer 141 from being reduced. A specific manufacturing process of the first channel layer 1411 and the second channel layer 1413 will be described later with reference to FIG. 6.

According to some example embodiments, the first channel layer 1411 and the second channel layer 1413 may each include an oxide semiconductor material. For example, the oxide semiconductor material may include at least one metal element selected from indium (In), gallium (Ga), and zinc (Zn), and, for example, may include InGaZnOx (IGZO), Sn-doped InGaZnOx (Sn-doped IGZO), W-doped InGaZnOx (W-doped IGZO), and InZnOx (IZO). The first channel layer 1411 may include amorphous IGZO (a-IGZO). The second channel layer 1413 may include crystalline IGZO (c-IGZO), and, for example, may include at least one of single crystalline IGZO, polycrystalline IGZO, spinel IGZO, and c-axis aligned crystalline IGZO (CAAC IGZO).

According to some example embodiments, a thickness w1 of the first channel layer 1411 may be within the range of 30 atoms to 50 atoms (e.g., 30 Å to 50 Å), and a thickness w2 of the second channel layer 1413 may be within the range of 40 atoms to 70 atoms (e.g., 40 Å to 70 Å). The thickness w1 of the first channel layer 1411 is formed within a size of 30 to 50 atoms, thereby reducing oxidation of the bit line BL located below the channel layer 141. Table 1 below shows a change in the thickness of a silicon oxide layer located below the first channel layer 1411 during the deposition process of the second channel layer 1413 according to the thickness w1 of the first channel layer 1411. For example, an initial thickness of the silicon oxide layer was 1.07 nanometers, and the oxygen partial pressure was set to 86% during the deposition process of the second channel layer 1413.

TABLE 1

| | Thickness of a first channel layer | | | |
|---|---|---|---|---|
| | 10 atoms | 20 atoms | 30 atoms | 40 atoms |
| Thickness of | 1.61 | 1.23 | 1.07 | 1.07 |
| a silicon | nanometers | nanometers | nanometers | nanometers |
| oxide layer | | | | |

In Table 1, when the thickness w1 of the first channel layer 1411 is deposited to a size of 10 atoms, the thickness of the silicon oxide layer located below the first channel layer 1411 increased from an initial thickness of 1.07 nanometers to 1.61 nanometers by 0.54 nanometers. When the thickness w1 of the first channel layer 1411 is deposited to a size of 20 atoms, the thickness of the silicon oxide layer located below the first channel layer 1411 may be increased from the initial thickness of 1.07 nanometers to 1.23 nanometers by 0.16 nanometers. When the thickness w1 of the first channel layer 1411 was deposited to within the range of 30 atoms to 40 atoms, the thickness of the silicon oxide layer located below the first channel layer 1411 may be kept at the initial thickness of 1.07 nanometers. Accordingly, a minimum thickness of the first channel layer 1411 for reducing oxidation of the bit line BL located below the first channel layer 1411 may be 30 atoms.

According to some example embodiments, the plurality of channel layers 141 may each be formed in a double-layer structure of the first channel layer 1411 and the second channel layer 1413 on the first channel layer 1411. However, some example embodiments are not limited thereto, and each of the plurality of channel layers 141 may also be formed in a structure in which the first channel layer 1411 and the second channel layer 1413 are alternately and sequentially deposited. For example, the plurality of channel layers 141 may each be formed in a structure in which the second channel layer 1413 is deposited on the first channel layer 1411, the first channel layer 1411 is deposited on the second channel layer 1413, and the second channel layer 1413 is deposited again on the first channel layer 1411.

A gate insulating layer 143 may be arranged on respective innerwalls of the plurality of channel layers 141. For example, the gate insulating layer 143 may be conformally disposed on the innerwall of the channel layer 141. A bottom of the gate insulating layer 143 may discontinuously extend along the bottom of the channel layer 141 to partially expose the channel layer 141.

The gate insulating layer 143 may be formed of at least one selected from a high-k dielectric material having a higher dielectric constant than silicon oxide and a ferroelectric material. According to some example embodiments, the gate insulating layer 143 may include at least one selected from hafnium oxide (HfO), hafnium silicate (HfSiO), hafnium oxynitride (HfON), hafnium silicon oxynitride (HfSiON), lanthanum oxide (LaO), lanthanum aluminum oxide (LaAIO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate (STB), bismuth iron oxide (BFO), strontium titanium oxide (SrTiO), yttrium oxide (YO), aluminum oxide (AlO), or lead scandium tantalum oxide (PbScTaO).

A word line WL may be disposed on the innerwall of the gate insulating layer 143. For example, the word line WL may be conformally disposed along the innerwall of the gate insulating layer 143. According to some example embodiments, an upper surface of the word line WL may be on a different level from an upper surface of the gate insulating layer 143 in the vertical direction (e.g., the Z direction). The upper surface of the word line WL may be on a lower level than the upper surface of the gate insulating layer 143 in the vertical direction (e.g., the Z direction). A portion of the upper surface of the word line WL that is adjacent to the gate insulating layer 143 may be on a higher level than the other portion thereof in the vertical direction (e.g., the Z direction). Accordingly, the upper surface of the word line WL may have a profile of an inclined surface having a higher level in the vertical direction (e.g., the Z direction) as the inclined surface approaches the gate insulating layer 143. A bottom of the word line WL may discontinuously extend along the bottom of the channel layer 141 to partially expose the channel layer 141. According to some example embodiments, the word line WL may include Ti, TiN, Ta, TaN, W, WN, TiSiN, WSiN, polysilicon, or a combination thereof.

One mold opening 131H may include a plurality of gate insulating layers 143 and a plurality of word lines WL. For example, one mold opening 131H may include two gate insulating layers 143 spaced apart from each other and two word lines WL spaced apart from each other. Among gate insulating layers 143 spaced apart from each other, one gate insulating layer 143 may be disposed to face the first sidewall 131H1 of a mold opening 131H, and the other gate insulating layer 143 may be disposed to face the second sidewall 131H2 of the mold opening 131H. Among word lines WL spaced apart from each other, one word line WL may be disposed to face the first sidewall 131H1 of a mold opening 131H, and the other word lines WL may be disposed to face the second sidewall 131H2 of the mold opening 131H. For example, the one gate insulating layer 143, the one word line WL, and a portion of the channel layer 141 that is connected to (e.g., in contact with) the one gate insulating layer 143 may constitute a first cell transistor CTR1. The other gate insulating layer 143, the other word line WL, and a portion of the channel layer 141 that is connected to (e.g., in contact with) the other gate insulating layer 143 may constitute a second cell transistor CTR2. Accordingly, the first cell transistor CTR1 and the second cell transistor CTR2 may be arranged in a mirror symmetrical shape within the one mold opening 131H.

An insulating liner 145 may be disposed on the innerwall of the word line WL. The insulating liner 145 may conformally extend along the inner wall of the word line WL and the inner wall of a portion of the gate insulating layer 143 that is not covered and that is exposed by the word line WL. An insulating barrier wall 147 may be disposed on the insulating liner 145. The insulating barrier wall 147 may be disposed between the first cell transistor CTR1 and the second cell transistor CTR2 to isolate the first cell transistor CTR1 from the second cell transistor CTR2. The insulating barrier wall 147 may fill a remaining space in the mold opening 131H on the insulating liner 145.

According to some example embodiments, each of the insulating liner 145 and the insulating barrier wall 147 may include a silicon oxide layer or a silicon nitride layer. For example, the insulating liner 145 may include a silicon nitride layer, the insulating barrier wall 147 may include a silicon oxide layer.

A plurality of conductive contact patterns 151 may be arranged on the first cell transistor CTR1 and the second cell transistor CTR2. As illustrated in FIG. 2, the plurality of conductive contact patterns 151 may be arranged in a regular layout at regular intervals in the first horizontal direction (e.g., the X direction) and the second horizontal direction (e.g., the Y direction). Although FIG. 2 illustrates an example in which the plurality of conductive contact patterns 151 are arranged in a matrix structure on a plane (e.g., an X-Y plane) on the substrate 110, the inventive concepts are not limited thereto. For example, the plurality of conductive contact patterns 151 may be arranged in a honeycomb structure on a plane (e.g., the X-Y plane) on the substrate 110. The plurality of conductive contact patterns 151 may be insulated from one another by an isolation insulating layer 155.

The plurality of conductive contact patterns 151 may extend to cover an upper portion of the mold layer 131 and respective upper portions of the first cell transistor CTR1 and the second cell transistor CTR2. Each of the plurality of conductive contact patterns 151 may be separated from a word line WL with a gate dielectric layer 143 therebetween. As illustrated in FIG. 3A, each of the plurality of conductive contact patterns 151 may include a lower contact portion 151L interposed between the gate insulating layer 143 and the mold layer 131, and an upper pad portion 151U disposed on and integrally connected to the lower contact portion 151L. The lower contact portion 151L of each of the plurality of conductive contact patterns 151 may have a sidewall facing the mold layer 131, a bottom surface contacting the upper surface of the channel layer 141, and a sidewall facing the gate insulating layer 143. The upper pad portion 151U of each of the plurality of conductive contact patterns 151 may cover respective upper surfaces of the mold layer 131, the gate insulating layer 143, the insulating liner 145, and the insulating barrier wall 147.

According to some example embodiments, each of the plurality of conductive contact patterns 151 may include Ti, TiN, Ta, TaN, Mo, Ru, W, WN, TiSiN, WSiN, or a combination thereof. For example, each of the plurality of conductive contact patterns 151 may have a stacked structure of a conductive barrier layer formed of TiN and a conductive layer formed of W.

According to some example embodiments, a vertical level of the upper surface of the channel layer 141 may be lower than respective vertical levels of the respective upper surfaces of the mold layer 131, the gate insulating layer 143, the insulating liner 145, and the insulating barrier wall 147. The term “vertical level” used herein may refer to a distance in a vertical direction (Z direction or −Z direction) from one surface of the substrate 110.

A plurality of isolation insulating layers 155 may be arranged to electrically separate a conductive contact pattern 151 connected to a first cell transistor CTR1 from a conductive contact pattern 151 connected to a second cell transistor CTR2. Each of the plurality of isolation insulating layers 155 may include a first isolation insulating layer 155a disposed on an insulating barrier wall 147 and a second isolation insulating layer 155b disposed on the mold layer 131. A lower portion of a sidewall of the first isolation insulating layer 155a may be surrounded by the insulating barrier wall 147, and an upper portion of the sidewall of the first isolation insulating layer 155a may be surrounded by the conductive contact pattern 151. A lower portion of a sidewall of the second isolation insulating layer 155b may be surrounded by the mold layer 131, and an upper portion of the sidewall of the second isolation insulating layer 155b may be surrounded by the conductive contact pattern 151. According to some example embodiments, each of the plurality of isolation insulating layers 155 may include a silicon nitride layer or a silicon oxide layer.

An etch stop layer 161 and an interlayer insulating layer 171 may be sequentially stacked on the plurality of conductive contact patterns 151 and the isolation insulating layer 155. A plurality of capacitor structures CAP may be arranged on the plurality of conductive contact patterns 151 and the isolation insulating layer 155. Each of the plurality of capacitor structures CAP may pass through the interlayer insulating layer 171 and the etch stop layer 161 in the vertical direction (e.g., the Z direction) and may be connected to one conductive contact pattern 151 selected from the plurality of conductive contact patterns 151. According to some example embodiments, the etch stop layer 161 may include a silicon nitride layer, and the interlayer insulating layer 171 may include a silicon oxide layer.

In general, a cell transistor of a DRAM device has a buried channel array transistor (BCAT) structure that uses a portion of a silicon substrate as a channel region. However, as the integration of DRAM devices improves, the size of the cell transistor also needs to be reduced, which causes a leakage current from the channel region of the cell transistor to increase. According to some example embodiments of the inventive concepts, a leakage current may be significantly reduced due to formation of a channel layer by using an oxide semiconductor material such as indium gallium zinc oxide.

According to some example embodiments of the inventive concepts, the channel layer 141 is formed in a double-layer structure of the first channel layer 1411 and the second channel layer 1413, and the first channel layer 1411 is formed of an amorphous material to minimize an oxygen partial pressure during deposition of the first channel layer 1411, thereby reducing oxidation of the bit line BL disposed below the first channel layer 1411. Because the second channel layer 1413 is formed of a crystalline material, carrier mobility may be maintained relatively high compared to the channel layer 141 including an amorphous single layer. Accordingly, a semiconductor device with improved electrical characteristics may be provided.

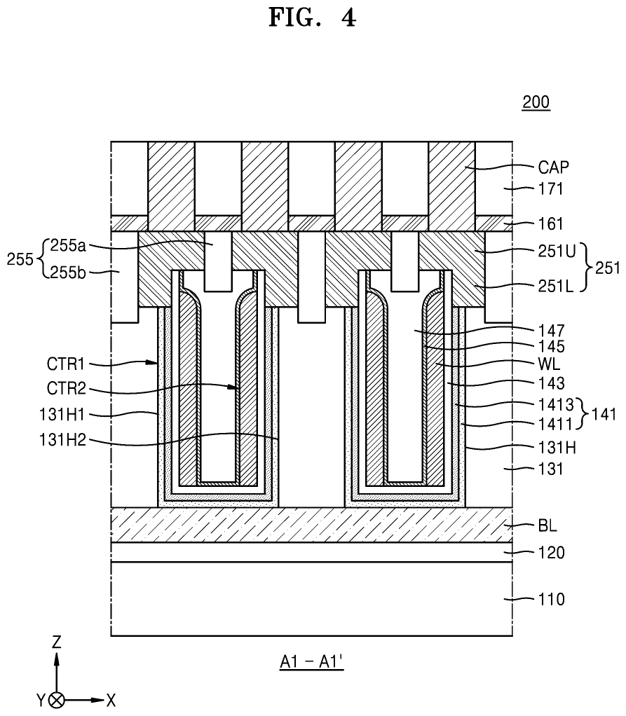

FIG. 4 is a cross-sectional view for explaining a semiconductor device 200 according to some example embodiments. FIG. 4 may correspond to a cross-section taken along line A-A′ in FIG. 2. Because the semiconductor device 200 is constituted almost similarly to the semiconductor device 100, the following will focus on differences from the semiconductor device 100. The same reference numerals are used for the same components among the components of the semiconductor device 200 as the semiconductor device 100, and their descriptions are simplified or omitted.

Referring to FIG. 4, the semiconductor device 200 may include a substrate 110, a lower insulating layer 120, a plurality of bit lines BL disposed on the lower insulating layer 120, and a plurality of shielding lines SL disposed on the lower insulating layer 120. A mold layer 131 may be disposed on a plurality of bit lines BL, a plurality of shielding lines SL, and the bit line insulating layer. The mold layer 131 may include a plurality of mold openings 131H. The plurality of mold openings 131H may have a first sidewall 131H1 and a second sidewall 131H2 that are opposite to each other. An upper surface of the bit line BL may be exposed via the bottom of each of the plurality of mold openings 131H.

A plurality of channel layers 141 may be disposed on a plurality of bit lines BL, a plurality of shielding lines SL, and the bit line insulating layer. Each of the plurality of channel layers 141 may extend conformally along inner walls of the plurality of mold openings 131H. The bottom of the channel layer 141 may contact the upper surface of the bit line BL exposed via the bottom of the mold opening 131H, and the upper surface of the channel layer 141 may contact a conductive contact pattern 251. For example, the upper surface of the channel layer 141 may be at substantially the same level in the vertical direction (e.g., the Z direction) as an upper surface of the mold layer 131.

According to some example embodiments, the plurality of channel layers 141 may each include a first channel layer 1411 and a second channel layer 1413 on the first channel layer 1411. For example, the first channel layer 1411 may extend conformally along the inner walls of the plurality of mold openings 131H, and the second channel layer 1413 may extend conformally on the first channel layer 1411.

According to some example embodiments, the first channel layer 1411 may be formed of an amorphous material, and the second channel layer 1413 may be formed of a crystalline material. According to some example embodiments, the crystallinity of the second channel layer 1413 may be 17% or more and 100% or less. The first channel layer 1411 may include amorphous IGZO (a-IGZO). The second channel layer 1413 may include crystalline IGZO (c-IGZO), and, for example, may include at least one of single crystalline IGZO, polycrystalline IGZO, spinel IGZO, and c-axis aligned crystalline IGZO (CAAC IGZO).

According to some example embodiments, a thickness of the first channel layer 1411 may be within the range of 30 atoms to 50 atoms, and a thickness of the second channel layer 1413 may be within the range of 40 atoms to 70 atoms.

A gate insulating layer 143 may be arranged on respective innerwalls of the plurality of channel layers 141. For example, the gate insulating layer 143 may be conformally disposed on the innerwall of the channel layer 141. A word line WL may be disposed on the innerwall of the gate insulating layer 143. For example, the word line WL may be conformally disposed along the innerwall of the gate insulating layer 143. An insulating liner 145 may be disposed on the innerwall of the word line WL. The insulating liner 145 may conformally extend along the inner wall of the word line WL and the inner wall of a portion of the gate insulating layer 143 that is not covered and that is exposed by the word line WL. An insulating barrier wall 147 may be disposed on the insulating liner 145. The insulating barrier wall 147 may be disposed between the first cell transistor CTR1 and the second cell transistor CTR2 to isolate the first cell transistor CTR1 from the second cell transistor CTR2.

A plurality of conductive contact patterns 251 may be arranged on the first cell transistor CTR1 and the second cell transistor CTR2. As illustrated in FIG. 2, the plurality of conductive contact patterns 251 may be arranged in a regular layout at regular intervals in the first horizontal direction (e.g., the X direction) and the second horizontal direction (e.g., the Y direction). Although FIG. 2 illustrates an example in which the plurality of conductive contact patterns 251 are arranged in a matrix structure on a plane (e.g., an X-Y plane) on the substrate 110, the inventive concepts are not limited thereto. For example, the plurality of conductive contact patterns 251 may be arranged in a honeycomb structure on a plane (e.g., the X-Y plane) on the substrate 110. The plurality of conductive contact patterns 251 may be insulated from one another by an isolation insulating layer 255.

The plurality of conductive contact patterns 251 may extend to cover an upper portion of the mold layer 131 and respective upper portions of the first cell transistor CTR1 and the second cell transistor CTR2. Each of the plurality of conductive contact patterns 251 may be separated from a word line WL with a gate dielectric layer 143 therebetween. As illustrated in FIG. 4, each of the plurality of conductive contact patterns 251 may include a lower contact portion 251L interposed between the gate insulating layer 143 and the isolation insulating layer 255, and an upper pad portion 251U disposed on and integrally connected to the lower contact portion 251L. The lower contact portion 251L of each of the plurality of conductive contact patterns 251 may have a bottom surface contacting the upper surface of the channel layer 141, a sidewall facing the gate insulating layer 143, and a sidewall facing the isolation insulating layer 255. The upper pad portion 251U of each of the plurality of conductive contact patterns 251 may cover respective upper surfaces of the gate insulating layer 143, the insulating liner 145, and the insulating barrier wall 147.

According to some example embodiments, each of the plurality of conductive contact patterns 251 may include Ti, TiN, Ta, TaN, Mo, Ru, W, WN, TiSiN, WSiN, or a combination thereof. For example, each of the plurality of conductive contact patterns 251 may have a stacked structure of a conductive barrier layer formed of TiN and a conductive layer formed of W.

A plurality of isolation insulating layers 255 may be arranged to electrically separate a conductive contact pattern 251 connected to a first cell transistor CTR1 from a conductive contact pattern 251 connected to a second cell transistor CTR2. Each of the plurality of isolation insulating layers 255 may include a first isolation insulating layer 255a disposed on an insulating barrier wall 147 and a second isolation insulating layer 255b disposed on the mold layer 131. A lower portion of a sidewall of the first isolation insulating layer 255a may be surrounded by the insulating barrier wall 147, and an upper portion of the sidewall of the first isolation insulating layer 255a may be surrounded by the conductive contact pattern 251. A lower portion of a sidewall of the second isolation insulating layer 255b may be surrounded by the mold layer 131, and an upper portion of the sidewall of the second isolation insulating layer 255b may be surrounded by the conductive contact pattern 251.

According to some example embodiments, respective vertical levels of the respective upper surfaces of the mold layer 131 and the channel layer 141 may be lower than respective vertical levels of the respective upper surfaces of the gate insulating layer 143, the insulating liner 145, and the insulating barrier wall 147. According to some example embodiments, the first isolation insulating layer 255a and the second isolation insulating layer 255b may have different vertical heights. For example, a vertical height of the second isolation insulating layer 255b may be greater than that of the first isolation insulating layer 255a. According to some example embodiments, each of the plurality of isolation insulating layers 255 may include a silicon nitride layer or a silicon oxide layer.

An etch stop layer 161 and an interlayer insulating layer 171 may be sequentially stacked on the plurality of conductive contact patterns 251 and the isolation insulating layer 255. A plurality of capacitor structures CAP may be arranged on the plurality of conductive contact patterns 251 and the isolation insulating layer 255.

As described above with reference to FIGS. 2, 3A, and 3B, the channel layer 141 is formed in a double-layer structure of the first channel layer 1411 and the second channel layer 1413, and the first channel layer 1411 is formed of an amorphous material to minimize an oxygen partial pressure during deposition of the first channel layer 1411, thereby reducing oxidation of the bit line BL disposed below the first channel layer 1411. Because the second channel layer 1413 is formed of a crystalline material, carrier mobility may be maintained relatively high compared to the channel layer 141 including an amorphous single layer. Accordingly, a semiconductor device with improved electrical characteristics may be provided.

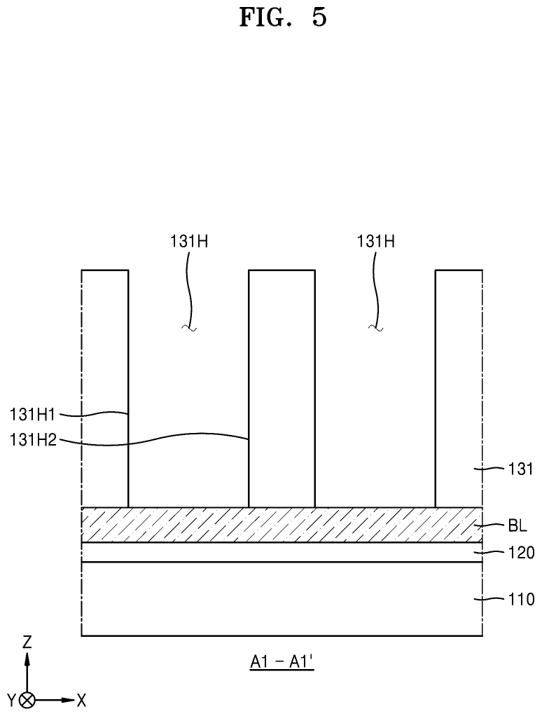

FIGS. 5 through 15 are cross-sectional views for explaining a method of manufacturing a semiconductor device, according to some example embodiments.

It may be understood that the same reference numerals in FIGS. 5 through 15 as those in FIGS. 1, 2, 3A, 3B, and 4 indicate the same components.

Referring to FIG. 5, a lower insulating layer 120 may be formed on the substrate 110. A plurality of bit lines BL and a plurality of shielding lines SL each extending in the first horizontal direction (e.g., the X direction) and spaced apart one another in the second horizontal direction (e.g., the Y direction), and a bit line insulating layer (not shown) filling a space between one of the plurality of lines BL and a shielding line SL adjacent thereto may be formed on the lower insulating layer 120.

For example, a bit line insulating layer may be formed on the lower insulating layer 120, a bit line formation space (not shown) may be formed by patterning the bit line insulating layer by using a mask pattern (not shown), and a conductive material may be stacked within the bit line formation space. Thereafter, an upper side of the conductive material may be removed until the upper surface of the bit line insulating layer is exposed, thereby forming a plurality of bit lines BL. Similarly, a shielding line formation space (not shown) may be formed by patterning the bit line insulating layer by using the mask pattern, and a conductive material may be stacked within the shielding line formation space. Thereafter, an upper side of the conductive material may be removed until the upper surface of the bit line insulating layer is exposed, thereby forming a plurality of shielding lines SL.

According to some example embodiments, each of the plurality of bit lines BL and the plurality of shielding lines SL may include a lower conductive barrier layer (not shown), a conductive layer (not shown), and an upper conductive barrier layer (not shown) that are sequentially stacked. For example, a bit line insulating layer may be formed on the lower insulating layer 120, a bit line formation space may be formed by patterning the bit line insulating layer by using a mask pattern, and a lower conductive barrier layer, a conductive layer, and an upper conductive barrier layer may be sequentially formed within the bit line formation space. Thereafter, respective upper sides of the lower conductive barrier layer, the conductive layer, and the upper conductive barrier layer may be removed until the upper surface of the bit line insulating layer is exposed, thereby forming a plurality of bit lines BL. Similarly, for example, a shielding line formation space may be formed by patterning the bit line insulating layer by using a mask pattern, and a lower conductive barrier layer, a conductive layer, and an upper conductive barrier layer may be sequentially formed within the shielding line formation space. Thereafter, respective upper sides of the lower conductive barrier layer, the conductive layer, and the upper conductive barrier layer may be removed until the upper surface of the bit line insulating layer is exposed, thereby forming a plurality of shielding lines SL.

A mold layer 131 may be formed on the plurality of bit lines BL, the plurality of shielding lines SL, and the bit line insulating layer 120. Although not shown in FIG. 5, after a lower etch stop layer (not shown) including at least one of silicon oxide, silicon nitride, and silicon oxynitride is formed on the plurality of shielding lines SL and the bit line insulating layer 120, the mold layer 131 may be formed on the lower etch stop layer. The lower etch stop layer may be formed of a material having a different etch selectivity from the mold layer 131.

Thereafter, a mask pattern (not shown) may be formed on the mold layer 131, and a plurality of mold openings 131H may be formed using the mask pattern as an etch mask. An upper surface of the bit line BL may be exposed via the bottom of each of the plurality of mold openings 131H. The plurality of mold openings 131H may have a first sidewall 131H1 and a second sidewall 131H2 that are opposite to each other.

Referring to FIG. 6, a preliminary channel layer 141P may be conformally formed on the mold layer 131 along the upper surface of the mold layer 131 and the inner wall of the mold opening 131H. According to some example embodiments, the preliminary channel layer 141P may include a first preliminary channel layer 1411P and a second preliminary channel layer 1413P. After the first preliminary channel layer 1411P is conformally deposited on the mold layer 131 along the upper surface of the mold layer 131 and the inner wall of the mold opening 131H, the second preliminary channel layer 1413P may be conformally deposited on the first preliminary channel layer 1411P.

According to some example embodiments, the first preliminary channel layer 1411P may be formed of an amorphous material, and the second preliminary channel layer 1413P may be formed of a crystalline material. According to some example embodiments, the crystallinity of the second preliminary channel layer 1413P may be 17% or more and 100% or less.

According to some example embodiments, the first preliminary channel layer 1411P and the second preliminary channel layer 1413P may each include an oxide semiconductor material. For example, the oxide semiconductor material may include at least one metal element selected from indium (In), gallium (Ga), and zinc (Zn), and, for example, may include InGaZnOx (IGZO), Sn-doped InGaZnOx (Sn-doped IGZO), W-doped InGaZnOx (W-doped IGZO), and InZnOx (IZO). The first preliminary channel layer 1411P may include amorphous IGZO (a-IGZO). The second preliminary channel layer 1413P may include crystalline IGZO (c-IGZO), and, for example, may include at least one of single crystalline IGZO, polycrystalline IGZO, spinel IGZO, and c-axis aligned crystalline IGZO (CAAC IGZO).

According to some example embodiments, the first preliminary channel layer 1411P may be deposited to have a thickness within the range of 30 atoms to 50 atoms, and the second preliminary channel layer 1413P may be deposited to have a thickness within the range of 40 atoms to 70 atoms. The thickness of the first preliminary channel layer 1411P is formed to have a size of within 30 to 50 atoms, thereby reducing oxidation of a bit line BL.

According to some example embodiments, the first preliminary channel layer 1411P and the second preliminary channel layer 1413P may be formed using at least one of a physical vapor deposition (PVD) process, a chemical vapor deposition (CVD) process, a low pressure CVD process, a plasma enhanced CVD process, a metal organic MOCVD (CVD) process, and an atomic layer deposition (ALD) process. According to some example embodiments, the first preliminary channel layer 1411P and the second preliminary channel layer 1413P may be formed using a PVD process. For example, E-beam evaporation, laser molecular beam epitaxy, pulsed laser deposition, sputtering, or ion plating may be used.

According to some example embodiments, when the first preliminary channel layer 1411P is deposited using a PVD process (e.g., a sputtering process), a deposition temperature may be within 200° C. to 400° C. and an oxygen partial pressure may be 0% or more and less than 10%, or the deposition temperature may be within 150° C. to 200° C. and the oxygen partial pressure may be 0% or more and less than 10%, or the deposition temperature may be within 100° C. to 150° C. and the oxygen partial pressure may be 0% or more and less than 10%. According to some example embodiments, when the second preliminary channel layer 1413P is deposited using a PVD process (e.g., a sputtering process), a deposition temperature may be within 200° C. to 400° C. and an oxygen partial pressure may be 10% or more and 100% or less, or the deposition temperature may be within 150° C. to 200° C. and the oxygen partial pressure may be 10% or more and 100% or less, 20% or more and 100% or less, or 45% or more and 100% or less. For example, when the deposition temperature is 150° C., the oxygen partial pressure may be 45% or more and 100% or less, and, when the deposition temperature is 200° C., the oxygen partial pressure may be 10% or more and 100% or less. Within this specification, an “oxygen partial pressure” may refer to the pressure of oxygen relative to the total pressure of argon and oxygen, unless otherwise defined.

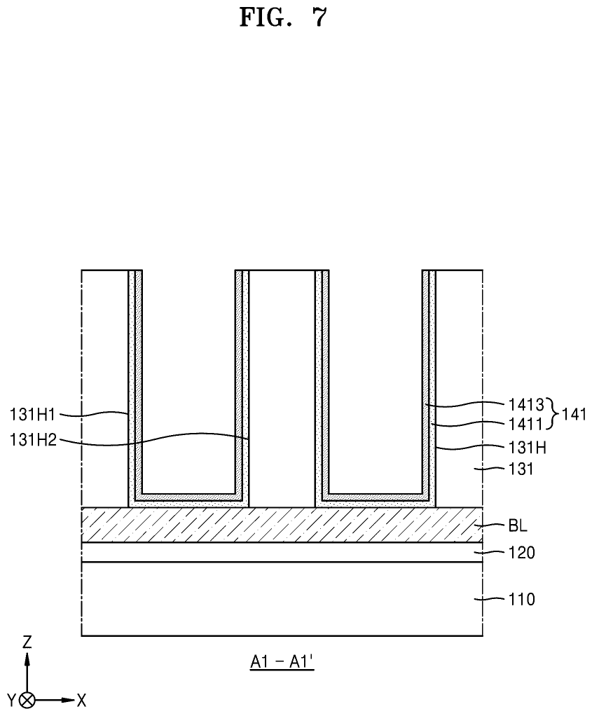

Referring to FIG. 7, a sacrificial mold layer (not shown) may be formed on the preliminary channel layer 141P. The sacrificial mold layer (not shown) may be formed to cover the upper surface of the preliminary channel layer 141P and fill the inside of the mold opening 131H. The sacrificial mold layer (not shown) may include at least one of silicon oxide, silicon nitride, and silicon oxynitride.

Thereafter, an upper portion of a structure in which the sacrificial mold layer (not shown) is formed on the preliminary channel layer 141P may be removed such that the sacrificial mold layer (not shown) inside the mold layer 131, the preliminary channel layer 141P, and the mold opening 131H may be exposed. A portion of the preliminary channel layer 141P that covers the upper surface of the mold layer 131 may be removed to form the channel layer 141.

Thereafter, a process of removing the exposed sacrificial mold layer (not shown) inside the mold opening 131H may be performed. Accordingly, the sacrificial mold layer (not shown) inside the mold opening 131H may be removed, and thus the channel layer 141 disposed on the bottom of the mold opening 131H may be exposed.

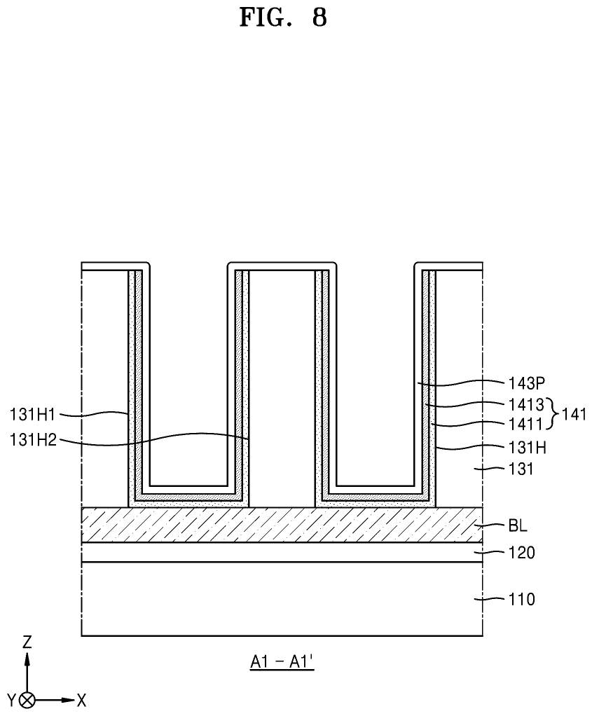

Referring to FIG. 8, a preliminary gate insulating layer 143P may be formed on the channel layer 141. The preliminary gate insulating layer 143P may be formed conformally along the upper surface of the mold layer 131 and the inner wall of the channel layer 141. The preliminary gate insulating layer 143P may be formed of at least one selected from a high-k dielectric material having a higher dielectric constant than silicon oxide and a ferroelectric material. According to some example embodiments, the preliminary gate insulating layer 143P may include at least one selected from hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate (STB), bismuth iron oxide (BFO), strontium titanium oxide (SrTiO), yttrium oxide (YO), aluminum oxide (AlO), or lead scandium tantalum oxide (PbScTaO).

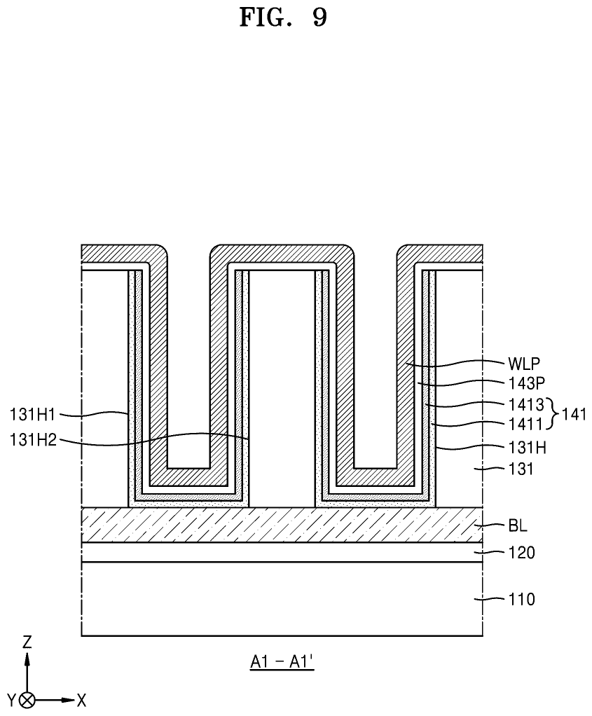

Referring to FIG. 9, a preliminary word line WLP may be formed on the preliminary gate insulating layer 143P. The preliminary word line WLP may be conformally disposed along the preliminary gate insulating layer 143P. The preliminary word line WLP may be formed using Ti, TiN, Ta, TaN, W, WN, TiSiN, WSiN, polysilicon, or a combination thereof.

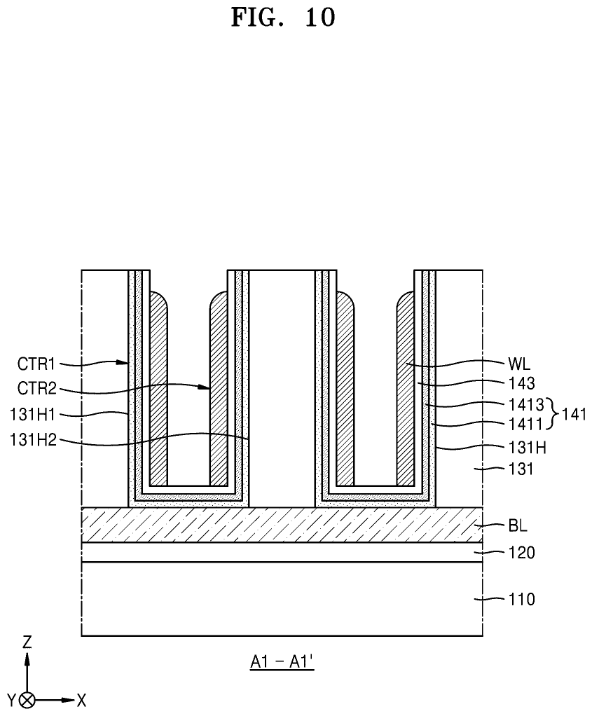

Referring to FIG. 10, an etching process may be performed on the preliminary word line WLP such that a portion of the preliminary word line WLP disposed on the upper surface of the mold layer 131 and a portion of the preliminary word line WLP disposed on the bottom of the mold opening 131H may be removed, and portions of the preliminary word line WLP respectively disposed on the first sidewall 131H1 and the second sidewall 131H2 of the mold opening 131H may remain. Accordingly, the preliminary word line WLP may be divided into two word lines WL respectively disposed on the first sidewall 131H1 and the second sidewall 131H2 of the mold opening 131H.

Through the etching process, a portion of the preliminary gate insulating layer 143P disposed on the upper surface of the mold layer 131 may also be removed, and a portion of the preliminary gate insulating layer 143P disposed on the bottom of the mold opening 131H and portions of the preliminary gate insulating layer 143P respectively disposed on the first sidewall 131H1 and the second sidewall 131H2 of the mold opening 131H may remain. According to some example embodiments, respective upper surfaces of the portions of the preliminary gate insulating layer 143P respectively disposed on the first sidewall 131H1 and the second sidewall 131H2 of the mold opening 131H may be formed on the same level in the vertical direction (e.g., the Z direction) as the upper surface of the channel layer 141. According to some example embodiments, although not shown in FIG. 10, the respective upper surfaces of the portions of the preliminary gate insulating layer 143P respectively disposed on the first sidewall 131H1 and the second sidewall 131H2 of the mold opening 131H may be formed at a lower level in the vertical direction (e.g., Z direction) than the upper surface of the channel layer 141. Accordingly, the gate insulating layer 143 may be formed from the preliminary gate insulating layer 143P.

According to some example embodiments, the etching process may be an anisotropic etching process. Through the etching process, a portion of the preliminary word line WLP disposed on the bottom of the mold opening 131H is removed, and thus the upper surface of a portion of the gate insulating layer 143 disposed on the bottom of the mold opening 131H may be exposed.

According to some example embodiments, through the etching process, not only the portion of the preliminary word line WLP disposed on the bottom of the mold opening 131H but also the portion of the preliminary gate insulating layer 143P disposed on the bottom of the mold opening 131H may be removed. For example, an upper surface of a portion of the channel layer 141 disposed on the bottom of the mold opening 131H may be exposed.

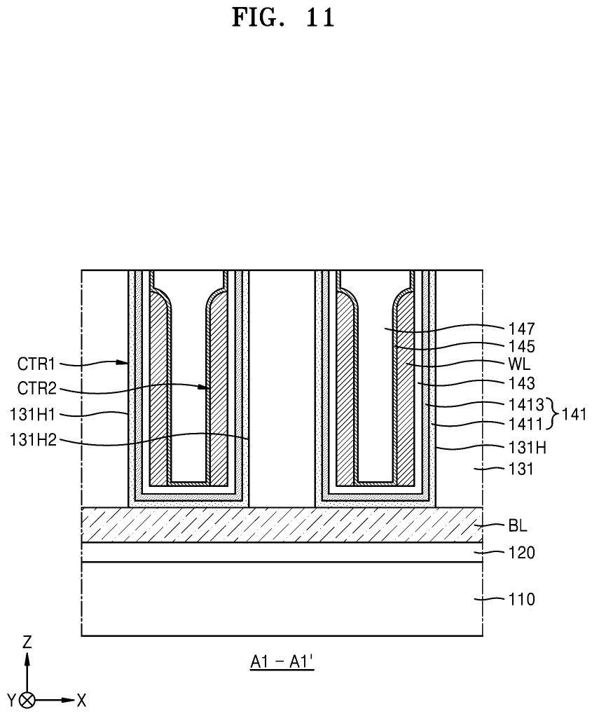

Referring to FIG. 11, an insulating liner 145 may be formed that conformally covers the inner walls of the plurality of word lines WL and an inner wall of the gate insulating layer 143 that is not covered and exposed by the plurality of word lines WL. Thereafter, an insulating barrier wall 147 filling the inner space of the mold opening 131H where the insulating liner 145 is formed may be formed within the mold opening 131H where the insulating liner 145 is formed.

According to some example embodiments, each of the insulating liner 145 and the insulating barrier wall 147 may include a silicon oxide layer or a silicon nitride layer. For example, the insulating liner 145 may include a silicon nitride layer, and the insulating barrier wall 147 may include a silicon oxide layer.

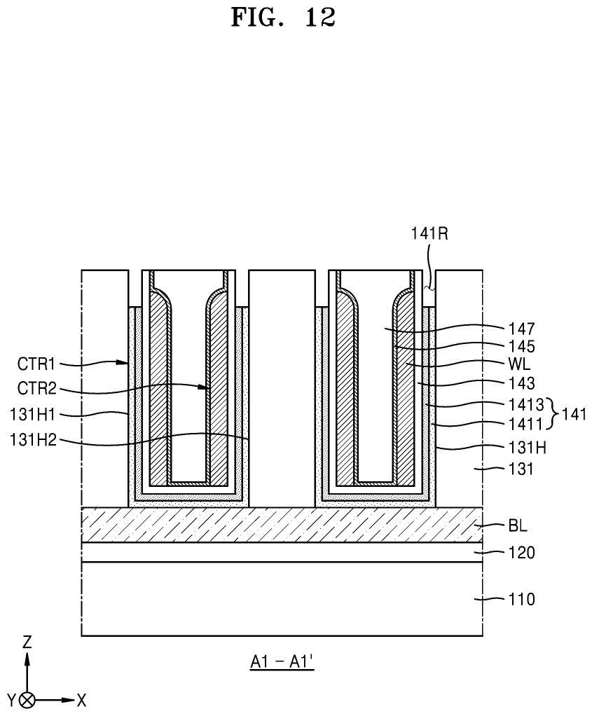

Referring to FIG. 12, a recess process may be performed on the upper surface of the channel layer 141 to remove the upper portion of the channel layer 141. The recess process may be performed using a wet process, a dry process, or a combination thereof. Accordingly, a plurality of channel recess spaces 141R limited to a space between the sidewall of the gate insulating layer 143 and the sidewall of the mold layer 131 may be formed on the channel layer 141. Through the recess process, the upper surface of the channel layer 141 may be on a lower level in the vertical direction (e.g., the Z direction) than the upper surface of the mold layer 131 and the upper surface of the gate insulating layer 143.

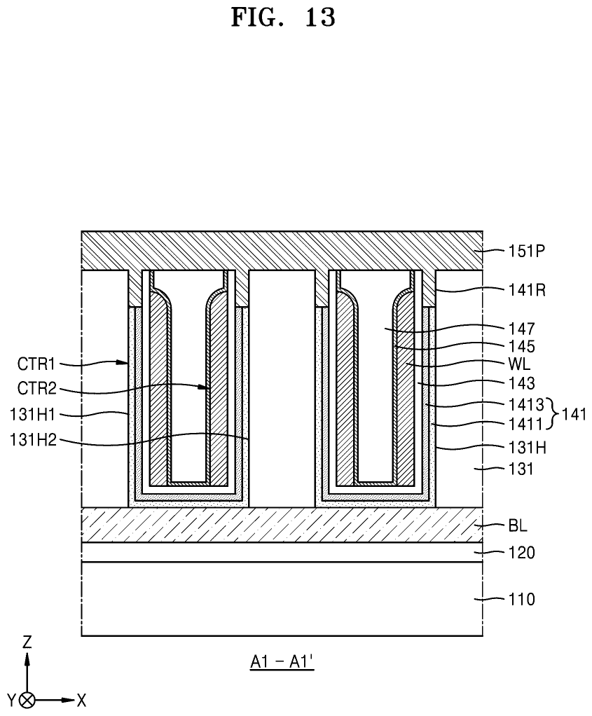

Referring to FIG. 13, a preliminary conductive contact layer 151P may be formed on the upper surface of the mold layer 131, the upper surface of the first cell transistor CTR1, and the upper surface of the second cell transistor CTR2. The preliminary conductive contact layer 151P may fill the plurality of channel recess spaces 141R and may each extend to cover the respective upper surfaces of the mold layer 131, the gate insulating layer 143, the insulating liner 145, and the insulating barrier wall 147. The preliminary conductive contact layer 151P may be formed in a stacked structure of a conductive barrier layer and a conductive layer. For example, the conductive barrier layer may be conformally formed on the upper surface of the first cell transistor CTR1 and the upper surface of the second cell transistor CTR2, and then a conductive layer may be deposited on the conductive barrier layer. According to some example embodiments, the preliminary conductive contact layer 151P may include Ti, TiN, Ta, TaN, W, WN, TiSiN, WSiN, polysilicon, or a combination thereof. For example, the preliminary conductive contact layer 151P may have a stacked structure of a conductive barrier layer formed of TiN and a conductive layer formed of W.

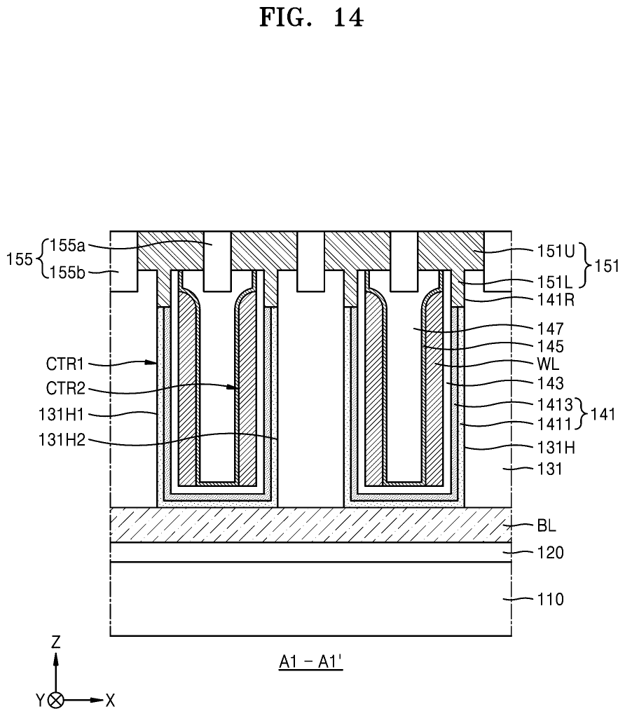

Referring to FIG. 14, a mask pattern (not shown) may be formed on the preliminary conductive contact layer 151P of FIG. 13, and a portion of the preliminary conductive contact layer 151P may be removed using the mask pattern to form a plurality of conductive contact patterns 151. Each of the plurality of conductive contact patterns 151 may include a lower contact portion 151L filling the plurality of channel recess spaces 141R, and an upper pad portion 151U disposed on and integrally connected to the lower contact portion 151L.

Thereafter, a plurality of isolation insulating layers 155 may be formed in an area from which the preliminary conductive contact layer 151P has been removed. According to some example embodiments, the plurality of isolation insulating layers 155 may be silicon oxide.

The plurality of isolation insulation layers 155 may include a first isolation insulating layer 155a and a second isolation insulating layer 155b. The first isolation insulating layer 155a may extend along a sidewall of the conductive contact pattern 151 and may extend through a portion of the insulating barrier wall 147. The second isolation insulating layer 155b may extend along a sidewall of the conductive contact pattern 151 and may extend through a portion of the mold layer 131.

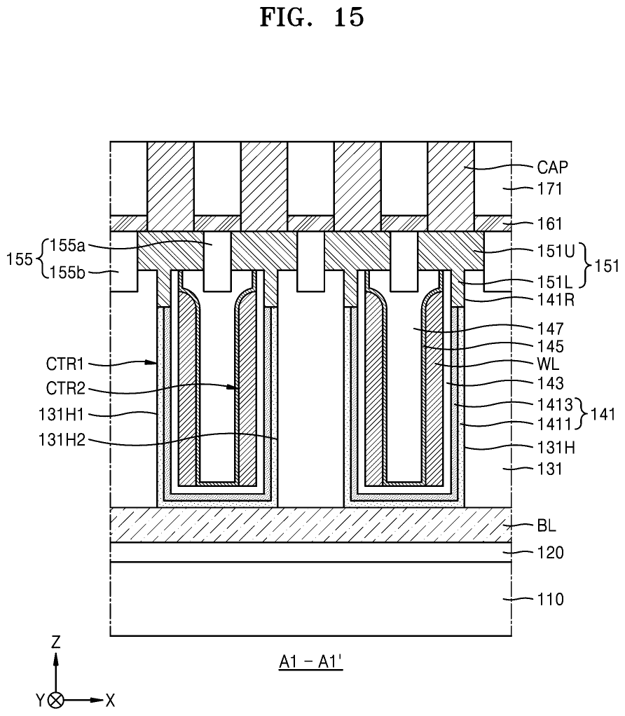

Referring to FIG. 15, an upper etch stop layer 161 may be formed on the conductive contact pattern 151 and the isolation insulating layer 155. The upper etch stop layer 161 and the interlayer insulating layer 171 may be formed, and a plurality of capacitor structures CAP connected to the plurality of conductive contact patterns 151 by penetrating through the upper etch stop layer 161 and the interlayer insulating layer 171 may be formed.

Although the method of manufacturing the semiconductor device 100 shown in FIGS. 1, 2, 3A, and 3B have been described above with reference to FIGS. 5 through 15, other semiconductor devices having various structures may be manufactured via various modifications and changes made within the technical spirit of the inventive concepts from the description given above with reference to FIGS. 5 through 15.

To form a structure such as the semiconductor device 200 of FIG. 4, a recess process may be performed on the upper surface of the channel layer 141 to remove the upper portion of the channel layer 141 from a resultant structure of FIG. 11. After the recess process is performed on the upper surface of the channel layer 141, a recess process may also be performed on the upper surface of the mold layer 131 to remove the upper portion of the mold layer 131. The recess process may be performed using a wet process, a dry process, or a combination thereof. Through the recess process on the upper surface of the channel layer 141 and the upper surface of the mold layer 131, the upper surface of the mold layer 131 may be located at a lower level in the vertical direction (e.g., the Z direction) than the upper surface of the gate insulating layer 143, and the upper surface of the mold layer 131 may be disposed at substantially the same level as the upper surface of the channel layer 141 in the vertical direction (e.g., the Z direction). However, the recess process on the upper surface of the mold layer 131 is not limited to being performed after the recess process on the upper surface of the channel layer 141, and may be performed before the recess process on the upper surface of the channel layer 141.

Thereafter, similar to the description given with respect to FIGS. 13 through 15, the preliminary conductive contact layer 151P covering the respective upper surfaces of the mold layer 131, the channel layer 141, the gate insulating layer 143, the insulating liner 145, and the insulating barrier wall 147 may be formed, a portion of the preliminary conductive contact layer 151P may be removed and divided into the plurality of conductive contact patterns 151, and the plurality of separation insulating layers 155 may be formed in the area from which the preliminary conductive contact layer 151P has been removed. The upper etch stop layer 161 may be formed on the plurality of conductive contact patterns 151 and the isolation insulating layer 155. The upper etch stop layer 161 and the interlayer insulating layer 171 may be formed, and a plurality of capacitor structures CAP connected to the plurality of conductive contact patterns 151 by penetrating through the upper etch stop layer 161 and the interlayer insulating layer 171 may be formed.

While the inventive concepts have been particularly shown and described with reference to embodiments thereof, it will be understood that various changes in form and details may be made therein without departing from the spirit and scope of the following claims.

What is claimed is:

1. A semiconductor device comprising:
a bit line on a substrate;
a mold layer over the bit line, the mold layer defining a mold opening, and the mold opening having a first sidewall and a second sidewall opposed to each other;
a channel layer conformally extending on the mold opening;
a plurality of word lines respectively on the first sidewall and the second sidewall of the mold opening; and
a gate insulating layer between the plurality of word lines and the channel layer,
wherein the channel layer comprises
a first channel layer composed of amorphous material, and
a second channel layer on the first channel layer, the second channel layer being composed of crystalline material.

2. The semiconductor device of claim 1, wherein
the first channel layer is formed of amorphous IGZO, and
the second channel layer is formed of crystalline IGZO.

3. The semiconductor device of claim 1, wherein a thickness of the first channel layer is within 30 to 50 angstroms.

4. The semiconductor device of claim 1, wherein a thickness of the second channel layer is within 40 to 70 angstroms.

5. The semiconductor device of claim 1, wherein
the first channel layer extends conformally on the mold opening, and
the second channel layer extends conformally on the first channel layer and covering the first channel layer.

6. The semiconductor device of claim 1, wherein a vertical level of an upper surface of the channel layer is equal to or lower than a vertical level of an upper surface of the mold layer.

7. The semiconductor device of claim 1, further comprising:
an insulating liner between the plurality of word lines; and
an insulating barrier wall having sidewalls surrounded by the insulating liner.

8. The semiconductor device of claim 1, further comprising:
a conductive contact being connected to an upper surface of the channel layer and extending in a vertical direction from the upper surface of the channel layer.

9. The semiconductor device of claim 1, further comprising:
an insulating liner between the plurality of word lines;
an insulating barrier wall having sidewalls surrounded by the insulating liner;
an isolation insulating layer partially penetrating through the insulating barrier wall and the mold layer in a vertical direction; and
a conductive contact having sidewalls surrounded by the isolation insulating layer.

10. The semiconductor device of claim 9, further comprising a capacitor structure over the conductive contact.

11. A semiconductor device comprising:
a bit line extending in a horizontal direction on a substrate;
a mold layer covering a portion of an upper surface of the bit line, the mold layer extending in a vertical direction from the upper surface of the bit line;
a channel layer covering a sidewall of the mold layer and covering a remaining portion of the upper surface of the bit line that is not covered by the mold layer;
a gate insulating layer conformally extending on the channel layer and covering the channel layer; and
a plurality of word lines having sidewalls facing sidewalls of the channel layer, the plurality of word lines being spaced apart from each other between the channel layer and the gate insulating layer,
wherein
the channel layer comprises
a first channel layer connected to the bit line, the first channel layer including an oxide semiconductor material containing at least one metal element selected from indium, gallium, and zinc, and the oxide semiconductor material being an amorphous material, and
a second channel layer spaced apart from the bit line, the first channel layer being between the second channel layer and the bit line, and
a thickness of the first channel layer is within 30 to 50 angstroms.

12. The semiconductor device of claim 11, wherein a thickness of the second channel layer is within 40 to 70 angstroms.

13. The semiconductor device of claim 11, wherein the second channel layer includes an oxide semiconductor material comprising at least one metal element selected from indium, gallium, and zinc, and the oxide semiconductor material of the second channel layer being a crystalline material.

14. The semiconductor device of claim 11, wherein
the second channel layer is a crystalline material, and
crystallinity of the second channel layer is 17% to 100%.

15. The semiconductor device of claim 11, wherein
the first channel layer extends conformally on the sidewall of the mold layer and the remaining portion of the upper surface of the bit line, and
the second channel layer extends conformally on the first channel layer and covering the first channel layer.

16. The semiconductor device of claim 11, wherein a vertical level of upper surfaces of the plurality of word lines is lower than a vertical level of an upper surface of the gate insulating layer.

17. The semiconductor device of claim 11, further comprising an insulating liner covering inner walls of the plurality of word lines and an upper portion of an inner wall of the gate insulating layer.

18. A semiconductor device comprising:
a plurality of bit lines each extending in a first horizontal direction on a substrate and spaced apart from each other in a second horizontal direction intersecting the first horizontal direction;
a mold layer covering a portion of an upper surface of a bit line from among the plurality of bit lines, the mold layer extending in a vertical direction from the upper surface of the bit line;
a channel layer covering sidewalls of the mold layer and covering a remaining portion of the upper surface of the bit line that is not covered by the mold layer;
a gate insulating layer conformally extending on the channel layer and covering the channel layer;
a plurality of word lines having sidewalls facing sidewalls of the channel layer, the plurality of word lines being spaced apart from the channel layer in the first horizontal direction, and the gate insulating layer being between the plurality of word lines and the channel layer;
an insulating barrier wall between the plurality of word lines and separating the plurality of word lines from one another;
an insulating liner conformally covering sidewalls and a lower surface of the insulating barrier wall; and
a plurality of conductive contact patterns over the channel layer and connected to the channel layer,
wherein the channel layer comprises
a first channel layer connected to the bit line, the first channel layer being amorphous IGZO, and
a second channel layer spaced apart from the bit line, the first channel layer being between the second channel layer and the bit line, and the second channel layer being crystalline IGZO.

19. The semiconductor device of claim 18, wherein the second channel layer includes at least one of single crystalline IGZO, polycrystalline IGZO, spinel IGZO, and c-axis aligned crystalline IGZO.

20. The semiconductor device of claim 18, wherein crystallinity of the second channel layer is 17% to 100%.
